(19) United States
(12) Patent Application Publication
(10) Pub. No.: US 2016/0234954 A1
(43) Pub. Date: Aug. 11, 2016

(54) MODULAR UPGRADEABLE VEHICLE INFOTAINMENT SYSTEM

(71) Applicant: Panasonic Automotive Systems Company of America, Division of Panasonic Corporation of North America, Peachtree City, GA (US)

(72) Inventors: HANS A. TROEMEL, Jr., SHARPSBURG, GA (US); THOMAS RAY BURNS, ATLANTA, GA (US); GERALD CLINTON DAVIS, FAYETTEVILLE, GA (US); MICHAEL T. BURK, PEACHTREE CITY, GA (US); CLAUS ANDERSEN, PEACHTREE CITY, GA (US)

(21) Appl. No.: 15/041,929

(22) Filed: Feb. 11, 2016

Related U.S. Application Data
(60) Provisional application No. 62/114,803, filed on Feb. 11, 2015.

(51) Int. Cl. H05K 7/10; H05K 7/02; G06F 1/16; B60R 11/02; H04N 5/225

(52) U.S. Cl. CPC H05K 7/10; B60R 11/0229; H04N 5/225; G06F 1/1632; H05K 7/026; B60R 2011/0288

(57) ABSTRACT

An infotainment arrangement for a motor vehicle includes a permanent portion permanently installed in the vehicle, The permanent portion includes a plurality of non-upgradeable electronic components. A non-permanent upgradeable portion is in electronic communication with the permanent portion. A non-permanent upgradeable portion is non-permanently installed in the vehicle and is replaceable in the vehicle.

### CROSS-REFERENCE TO RELATED APPLICATIONS

This application claims the benefit of U.S. Provisional Application No. 62/114,803, filed on Feb. 11, 2015, which the disclosure of which is hereby incorporated by reference in its entirety for all purposes.

### FIELD OF THE INVENTION

The disclosure relates to an infotainment system for a motor vehicle for any mode of transportation.

### BACKGROUND OF THE INVENTION

Infotainment systems on motor vehicles are generally not upgradeable. The consumer electronics market not only changes software but continuously upgrades the electronics, as well. This constant rapid evolution of the consumer market quickly forces the electronics of the infotainment system to become obsolete within a few years, and yet the vehicle may be in service for over ten years. Thus, the majority of a vehicle's life may be spent with obsolete electronics.

### SUMMARY

Disclosed herein is a system partitioning and architecture wherein it is possible to upgrade, swap out, or exchange a module or modules that include the wired and/or wireless in-cabin interfaces to communicate with consumer electronics, upgrade the processing of vehicle/infotainment audio/video/data, and/or increase internet/data bandwidth for vehicle/infotainment applications.

The system partitioning/architecture provides a physical division between the permanent automotive original equipment manufacturer (OEM) vehicle-centric components and the modular upgradable components. The permanent components may include an external radio frequency (RF) interface (e.g., broadcast audio systems, broadcast television systems, cellular systems, global navigation satellite system (GNSS) receivers, wireless transceivers, etc.), audio power amplifiers, automotive displays/clusters/heads up displays (HUD), and/or vehicular communication buses. All of these elements may be tailored or tuned to the aspect of the vehicle for best performance or styling. In contrast, the modular upgradeable components may include the main processor or system on chip (SoC) of the infotainment system along with the latest electronic, mechanical, or software interfaces to the consumer devices (phones, tablets, etc.). The permanent and modular systems may be connected via high bandwidth bi-directional audio/video/data communication buses and signaling.

The invention may provide the ability to upgrade the vehicle infotainment system with minimal impact to the factory-installed vehicle systems over the lifetime of the vehicle. This architecture provides the ability to keep better pace with the current state of consumer electronics, while possibly adding features to the vehicle system in the future as well. In essence, the inventive architecture future-proofs the vehicle infotainment system. The architecture enables quick and cost effective upgrading of the components of the system that are most likely to be in need of an upgrade in the future.

In one embodiment, the invention comprises deploying a basic but complete infotainment system on all vehicles, and then adding any additional desired components or features for certain models of vehicles without impacting the base system.

The architecture binds the system to the elements that are vehicle specific, leaving open many possible upgrade paths that are more specific to the human-machine interface (HMI), user experience, external connectivity, and other technologies that are not necessarily a part of the vehicle-specific components.

A core hardware system can be qualified for use and deployed across a broad range of vehicles. The features or capabilities are upgraded without having knowledge in advance of what those features or capabilities might be, because the core system can hand over control to one of the newly installed components. These upgrades can be installed without having to re-qualify the already installed components.

The system may be upgraded by replacement and/or exchanging of the modular units. This approach avoids system redundancy and maintains cost effectiveness. In one embodiment, a factory installed unit has a main system on chip (SoC) and connections with a blank or empty dock. This approach saves the cost of the modular unit housing and power supplies. This method is valid, but provides redundancy to the overall system cost once the first modular unit is applied.

In one embodiment, the invention comprises an infotainment arrangement for a motor vehicle including a permanent portion permanently installed in the vehicle. The permanent portion includes a plurality of non-upgradeable electronic components. A non-permanent upgradeable portion is in electronic communication with the permanent portion. A non-permanent upgradeable portion is non-permanently installed in the vehicle and is replaceable in the vehicle.

In another embodiment, the invention comprises a method of maintaining an infotainment system in a motor vehicle, including permanently installing a permanent portion of the infotainment system in the vehicle. The permanent portion includes a plurality of non-upgradeable electronic components. A non-permanent upgradeable portion of the infotainment system is non-permanently installed in the vehicle. Electronic communication is performed between the permanent portion and the non-permanent upgradeable portion. The non-permanent upgradeable portion is removed from the vehicle. An upgraded non-permanent portion is re-installed in the vehicle.

In yet another embodiment, the invention comprises a motor vehicle including an infotainment arrangement having a permanent portion permanently installed in the vehicle. The permanent portion has a plurality of non-upgradeable electronic components. A non-permanent upgradeable portion is electronically connected to the permanent portion. The non-permanent upgradeable portion is non-permanently installed in the vehicle and is replaceable in the vehicle. The non-permanent upgradeable portion is removed from the vehicle by pulling the non-permanent upgradeable portion out of the vehicle in a first single, linear motion in a first direction. The non-permanent upgradeable portion is installed in the vehicle by pushing the non-permanent upgradeable portion into a recess of the vehicle in a second single, linear motion in a second direction opposite to the first direction.

### BRIEF DESCRIPTION OF THE DRAWINGS

A better understanding of the present invention will be had upon reference to the following description in conjunction with the accompanying drawings.

FIG. 1 is a block diagram of one example embodiment of a vehicle infotainment system of the present invention.

FIG. 2 is a schematic diagram of a method of installing a non-permanent upgradeable portion of an infotainment system into a recess of the vehicle and removing the non-permanent upgradeable portion from the recess of the vehicle.

### DETAILED DESCRIPTION OF THE PREFERRED EMBODIMENTS

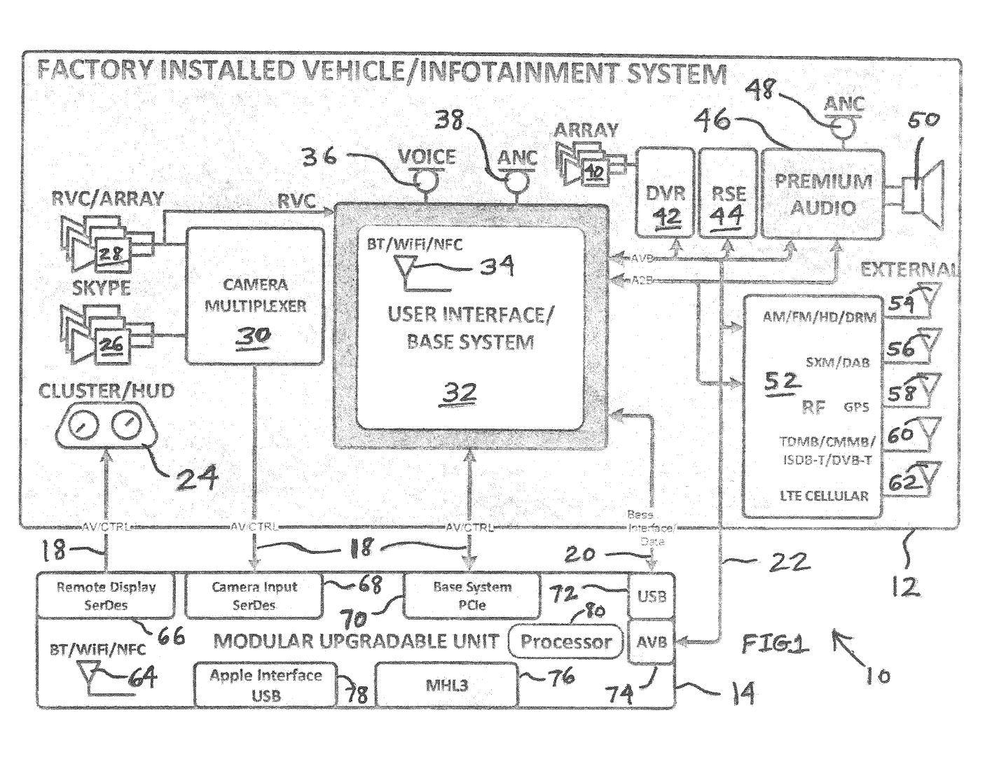

FIG. 1 illustrates one embodiment of a vehicle infotainment system 10 of the present invention including a permanently factory installed portion 12 and an upgradeable modular unit 14. Each of permanent portion 12 and modular unit 14 may be contained in a separate, respective housing. Permanent portion 12 and modular unit 14 may be interconnected by a connector arrangement 16 including one or more cables and connectors. The conductive lines within the connector arrangement 16 include audio/video data bus along with control signaling 18, a base interface/data signaling 20, and an audio/video bridge (AVB) signaling 22 which may carry time-stamped Ethernet data.

Each of audio/video data bus along with control signaling 18 may carry uncompressed data without any latency. In one embodiment, each of audio/video data bus along with control signaling 18 may carry about three gigabits of data in each direction.

In the embodiment shown, permanently factory installed portion 12 includes an instrument cluster/heads up display (HUD) 24, Skype cameras 26, Rear View Camera (RVC)/array cameras 28, a camera multiplexer 30, a user interface/base system 32 having a HT (Bluetooth)/WIFI/NFC (near field communication) antenna 34, a voice microphone 36, an ancillary microphone 38, a camera array 40, a digital video recorder (DVR) 42, rear seat entertainment (ME) subsystem 44, a premium audio subsystem 46, an ancillary microphone 48, a loudspeaker 50, and a radio frequency (RE) antenna array 52 including an AM/FM/high definition (HD)/digital radio mondiale (DRM) antenna 54, a SiriusXM (SXM)/digital audio broadcasting (DAB) antenna 56, a global positioning system (GPS)/GNSS antenna 58, a Terrestrial-Digital Multimedia Broadcasting (T-DMB)/China Mobile Multimedia Broadcasting (CMMB)/Integrated Services Digital Broadcasting-Terrestrial (ISDB-T)/Digital Video Broadcasting-Terrestrial (DVB-T) antenna 60, and a long-term evolution (LTE) cellular antenna 62.

In the embodiment shown, upgradeable modular unit 14 includes a BT/WiFi/NFC antenna 64, a remote display serializer/deserializer 66, a camera input serializer/deserializer 68, a base system PCIe 70, a USB port 72, an audio/video bridge 74, mobile high-definition link (MHL3) 76, an Apple Interface USB port 78, and a microprocessor 80 in communication with each of the other above-identified components of upgradeable modular unit 14. Apple Interface USB port 78 may be connectable to a personal electronic device, such as a mobile phone. A processor in the personal electronic device may be used as the primary processor of, and may perform most of the processing for, vehicle infotainment system 10.

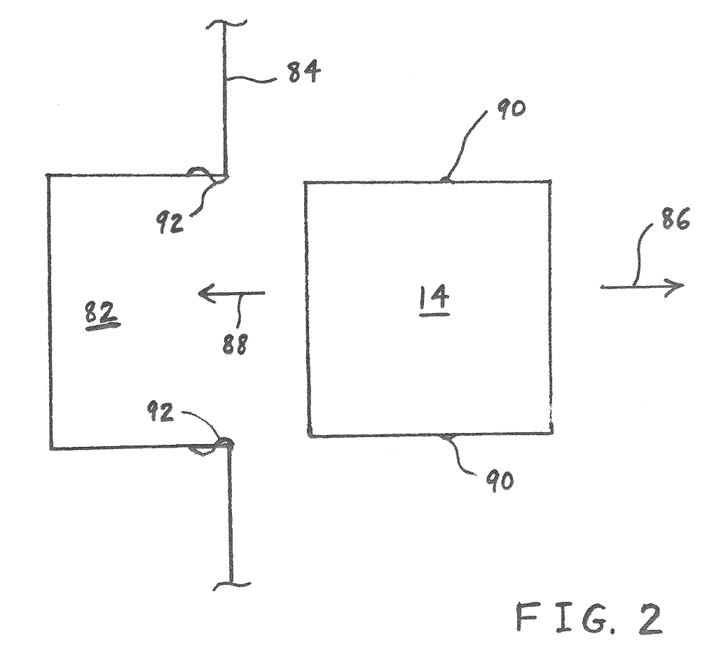

During use, the components of upgradeable modular unit 14 may become obsolete due to age and/or better or more widely accepted technology coming to the consumer electronics market. When such obsolescence of one or more of the components of upgradeable modular unit 14 occurs, the owner of the vehicle may swap out the obsolete modular unit 14 with an upgraded modular unit 14. The owner of the vehicle may swap out modular unit 14 himself by disconnecting the obsolete modular unit 14 from the vehicle dashboard. In one embodiment illustrated in FIG. 2, modular unit 14 may be disconnected from the vehicle dashboard 84 simply by pulling modular unit 14 out of a recess 82 in a dashboard 84 in a single linear motion in direction 86. Similarly, the new, upgraded modular unit 14 may be inserted into dashboard 84 by simply pushing modular unit 14 into recess 82 in dashboard 84 in a single linear motion in direction 88 until it snaps into place by virtue of opposing snap connectors 90, 92 on modular unit 14 and in recess 82, respectively. Although snap connectors 90, 92 may hold modular unit 14 within recess 82, manual pulling three may be sufficient to overcome the bias of snap connectors 90, 92 and remove modular unit 14 from recess 82. The direction of pushing 88 may be in a direction opposite to the direction 86 in which unit 14 was pulled out during removal. Modular unit 14 may be hot swappable such that the new modular unit. 14 is operable as soon as it is snapped into place.

In another embodiment, specialized or customized tools are required to remove the obsolete modular unit 14 from the dashboard such that replacing modular unit 14 with another one must be performed by personnel at the dealership who have the required tools.

The foregoing detailed description is given primarily for clearness of understanding and no unnecessary limitations are to be understood therefrom for modifications can be made by those skilled in the art upon reading this disclosure and may be made without departing from the spirit of the invention.

What is claimed is:

1. An infotainment arrangement for a motor vehicle, comprising:
a permanent portion configured to he permanently installed in the vehicle, the permanent portion including a plurality of non-upgradeable electronic components; and
a non-permanent upgradeable portion in electronic communication with the permanent portion, the non-permanent upgradeable portion being configured to be non-permanently installed in the vehicle and to be replaceable in the vehicle.

2. The arrangement of claim 1 wherein the non-permanent upgradeable portion is connected to the permanent portion by at least one cable or connector.

3. The arrangement of claim 1 wherein the non-permanent upgradeable portion is configured to be communicatively coupled to a personal electronic device.

4. The arrangement of claim 3 wherein the non-permanent upgradeable portion is configured to use a processor in the personal electronic device to perform a majority of processing required by the arrangement.

5. The arrangement of claim 1 wherein the non-permanent upgradeable portion is configured to be removed from the vehicle by pulling the non-permanent upgradeable portion out of the vehicle in a first single, linear motion in a first direction, and the non-permanent upgradeable portion is configured to be installed in the vehicle by pushing the non-permanent upgradeable portion into a recess of the vehicle in a second single, linear motion in a second direction opposite to the first direction until the non-permanent upgradeable portion snaps into place.

6. The arrangement of claim 1 wherein the permanent portion includes at least one camera, at least one microphone, an instrument cluster, a user interface, at least one antenna, and at least one loudspeaker.

7. The arrangement of claim 1 wherein the non-permanent upgradeable portion includes a microprocessor and at least one communication port.

8. A method of maintaining an infotainment system in a motor vehicle, comprising:
permanently installing a permanent portion of the infotainment system in the vehicle, the permanent portion including a plurality of non-upgradeable electronic components;
non-permanently installing a non-permanent upgradeable portion of the infotainment system in the vehicle;
performing electronic communication between the permanent portion and the non-permanent upgradeable portion;
removing the non-permanent upgradeable portion from the vehicle; and
re-installing an upgraded non-permanent portion in the vehicle.

9. The method of claim 8 wherein the upgraded non-permanent portion is installed in the vehicle at a same place in a dashboard of the vehicle as the replaced non-permanent portion was previously installed.

10. The method of claim 8 further comprising connecting the non-permanent upgradeable portion to the permanent portion by at least one cable or connector.

11. The method of claim 8 further comprising communicatively coupling the non-permanent upgradeable portion to a personal electronic device.

12. The method of claim 11 further comprising using a processor in the personal electronic device to perform a majority of processing required by the system.

13. The method of claim 8 further comprising:
removing the non-permanent upgradeable portion from the vehicle by pulling the nonpermanent upgradeable portion out of the vehicle in a first single, linear motion in a first direction; and
installing the upgraded non-permanent portion in the vehicle by pushing the upgraded non-permanent portion into a recess of the vehicle in a second single, linear motion in a second direction opposite to the first direction.

14. A motor vehicle, comprising an infotainment arrangement including:
a permanent portion permanently installed in the vehicle, the permanent portion having a plurality of non-upgradeable electronic components; and
a nonpermanent upgradeable portion electronically connected to the permanent portion, the non-permanent upgradeable portion being non-permanently installed in the vehicle and being replaceable in the vehicle, the nonpermanent upgradeable portion being configured to be:
removed from the vehicle by pulling the non-permanent upgradeable portion out of the vehicle in a first single, linear motion in a first direction; and
installed in the vehicle by pushing the nonpermanent upgradeable portion into a recess of the vehicle in a second single, linear motion in a second direction opposite to the first direction.

15. The arrangement of claim 14 wherein the nonpermanent upgradeable portion is connected to the permanent portion by at least one cable or connector.

16. The arrangement of claim 14 wherein the non-permanent upgradeable portion is configured to be communicatively coupled to a personal electronic device.

17. The arrangement of claim 16 wherein the nonpermanent upgradeable portion is configured to use a processor in the personal electronic device to perform a majority of processing required by the arrangement.

18. The arrangement of claim 14 wherein the permanent portion is contained within a first housing, and the non-permanent upgradeable portion is contained within a second housing.

19. The arrangement of claim 14 wherein the permanent portion includes at least one camera, at least one microphone, an instrument cluster, a user interface, at least one antenna, and at least one loudspeaker.

20. The arrangement of claim 14 wherein the non-permanent upgradeable portion includes a microprocessor and at least one communication port.
